(19) United States
(12) Patent Application Publication
(10) Pub. No.: US 2022/0223388 A1
(43) Pub. Date: Jul. 14, 2022

(54) EXHAUST RING ASSEMBLY AND PLASMA PROCESSING APPARATUS

(71) Applicant: Tokyo Electron Limited, Tokyo (JP)

(72) Inventor: Ryota SAKANE, Miyagi (JP)

(21) Appl. No.: 17/569,782

(22) Filed: Jan. 6, 2022

(30) Foreign Application Priority Data
Jan. 8, 2021 (JP) 2021-002316

(51) Int. Cl. H01J 37/32

(52) U.S. Cl. CPC H01J 37/32834; H01J 37/32642; H01J 37/3244

(57) ABSTRACT

An exhaust ring assembly disposed around a substrate support, includes: a first annular member having first exhaust holes and first rod-shaped portions alternately arranged in a circumferential direction, each of the first exhaust holes extending in a radial direction and each of the first rod-shaped portions extending in the radial direction; and a second annular member disposed below the first annular member and having second exhaust holes and second rod-shaped portions alternately arranged in the circumferential direction, each of the second exhaust holes extending in the radial direction and each of the second rod-shaped portions extending in the radial direction, wherein the first rod-shaped portions and the second rod-shaped portions do not overlap each other when viewed from above and at least one of each of the first rod-shaped portions and each of the second rod-shaped portions has an upwardly-tapered shape.

### CROSS-REFERENCE TO RELATED APPLICATION

This application is based upon and claims the benefit of priority from Japanese Patent Application No. 2021-002316, filed on Jan. 8, 2021, the entire contents of which are incorporated herein by reference.

### TECHNICAL FIELD

The present disclosure relates to an exhaust ring assembly and a plasma processing apparatus.

### BACKGROUND

Patent Document 1 discloses a parallel type exhaust ring in which two members are arranged to overlap each other in the horizontal direction. Patent Document 2 discloses a cylindrical exhaust ring in which two members are arranged to overlap each other in the vertical direction.

Each of the exhaust rings has a double structure in which two members having exhaust holes are arranged in an overlapping manner. In this case, gas passes through an exhaust hole in the member located at the upstream side with respect to a gas flow direction. Subsequently, the gas flow direction is changed to be approximately vertical, and is further changed to be approximately vertical when passing through an exhaust hole in the member located at the downstream side so that the gas is exhausted.

### PRIOR ART DOCUMENTS

### Patent Documents

Patent Document 1: Japanese Laid-Open Patent Publication No. 2004-006574

Patent Document 2: Japanese Laid-Open Patent Publication No. 2004-327767

Incidentally, in the exhaust ring, when the opening ratio is increased by enlarging the exhaust hole, the exhaust efficiency is improved, but plasma is more likely to leak from the plasma processing space to the exhaust space. Therefore, there is a trade-off relationship between the exhaust efficiency of the exhaust ring and the confinement effect of the plasma.

### SUMMARY

According to one embodiment of the present disclosure, an exhaust ring assembly disposed around a substrate support includes: a first annular member having a plurality of first exhaust holes and a plurality of first rod-shaped portions alternately arranged in a circumferential direction, each of the plurality of first exhaust holes extending in a radial direction and each of the plurality of first rod-shaped portions extending in the radial direction; and a second annular member disposed below the first annular member and having a plurality of second exhaust holes and a plurality of second rod-shaped portions alternately arranged in the circumferential direction, each of the plurality of second exhaust holes extending in the radial direction and each of the plurality of second rod-shaped portions extending in the radial direction, wherein the plurality of first rod-shaped portions and the plurality of second rod-shaped portions do not overlap each other when viewed from above, and at least one of each of the plurality of first rod-shaped portions and each of the plurality of second rod-shaped portions has an upwardly-tapered shape.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a view illustrating an example of a plasma processing system according to an embodiment.

FIG. 2 is a vertical cross-sectional view illustrating an example of a plasma processing apparatus according to an embodiment.

FIGS. 3A to 3C are views illustrating examples of exhaust rings according to an embodiment.

FIGS. 4A and 4B are views illustrating an example of an exhaust ring according to an embodiment.

FIGS. 5A and 5B are a top view and a cross-sectional view of a portion of an exhaust ring according to an embodiment.

FIGS. 6A to 6C are views illustrating examples of flows of gas passing through exhaust rings according to an embodiment and a comparative example.

FIGS. 7A and 7B are views illustrating examples of flows of gas passing through exhaust rings according to another comparative example.

FIGS. 8A to 8C are views illustrating an example of a method of thermal spraying an exhaust ring according to an embodiment in comparison with a comparative example.

FIGS. 9A to 9C are views illustrating an example of a method of thermal spraying an exhaust ring according to an embodiment in comparison with a comparative example.

### DETAILED DESCRIPTION

Hereinafter, embodiments of the present disclosure will be described with reference to the accompanying drawings. In the drawings, there are cases where the same components are designated by like reference numerals with the repeated descriptions thereof omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

[Plasma Processing System]

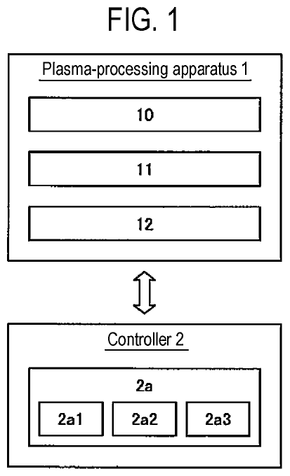

First, a plasma processing system according to an embodiment will be described with reference to FIG. 1. FIG. 1 is a view illustrating an example of the plasma processing system according to an embodiment. In an embodiment, the plasma processing system includes a plasma processing apparatus 1 and a controller 2. The plasma processing apparatus 1 includes a plasma processing chamber 10, a substrate support 11, and a plasma generator 12. The plasma processing chamber 10 includes a plasma processing space. In addition, the plasma processing chamber 10 includes at least one gas supply port configured to supply at least one processing gas to the plasma processing space, and at least one gas discharge port configured to discharge gas from the plasma processing space. The gas supply port is connected to a gas supplier 20 to be described later, and the gas discharge port is connected to an exhaust system 40 to be described later. The substrate support 11 is arranged in the plasma processing space and has a substrate support surface for supporting a substrate.

The plasma generator 12 is configured to generate plasma from the at least one processing gas supplied into the plasma processing space. The plasma formed in the plasma processing space may be capacitively coupled plasma (CCP), inductively coupled plasma (ICP), electron-cyclotron-resonance (ECR) plasma, helicon wave plasma (HWP), surface wave plasma (SWP), or the like. In addition, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHz. Therefore, the AC signal includes a radio frequency (RF) signal and a microwave signal. In an embodiment, the RF signal has a frequency in the range of 200 kHz to 150 MHz.

The controller 2 processes computer-executable commands that cause the plasma processing apparatus 1 to execute various processes described in the present disclosure. The controller 2 may be configured to control each element of the plasma processing apparatus 1 to perform various steps described herein. In an embodiment, a portion or all of the controller 2 may be included in the plasma processing apparatus 1. The controller 2 may include, for example, a computer 2a. The computer 2a may include, for example, a processing part (a central processing unit (CPU)) 2a1, a storage part 2a2, and a communication interface 2a3. The processing part 2a1 may be configured to perform various control operations based on a program stored in the storage part 2a2. The storage part 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### [Plasma Processing Apparatus]

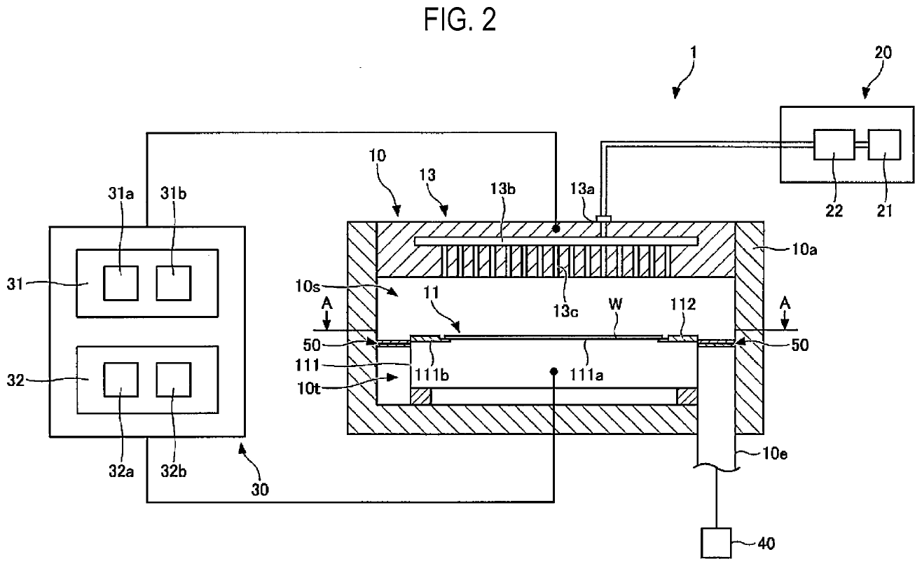

Next, a configuration example of a capacitively coupled plasma processing apparatus as an example of the plasma processing apparatus 1 will be described with reference to FIG. 2. FIG. 2 is a vertical cross-sectional view illustrating an example of the plasma processing apparatus 1 according to an embodiment.

The plasma processing apparatus 1 includes a plasma processing chamber 10, a gas supplier 20, a power supply 30, and an exhaust system 40. In addition, the plasma processing apparatus 1 includes a substrate support 11 and a gas introduction part. The gas introduction part is configured to introduce the at least one processing gas into the plasma processing chamber 10. The gas introduction part includes a shower head 13. The substrate support 11 is arranged in the plasma processing chamber 10. The shower head 13 is arranged above the substrate support 11. In an embodiment, the shower head 13 constitutes at least a portion of the ceiling of the plasma processing chamber 10. The plasma processing chamber 10 includes a plasma processing space 10s defined by the shower head 13, a sidewall 10a of the plasma processing chamber 10, and the substrate support 11. The sidewall 10a is grounded. The shower head 13 and the substrate support 11 are electrically insulated from a housing of the plasma processing chamber 10.

The substrate support 11 includes a main body 111 and a ring assembly 112. The main body 111 includes a central region (a substrate support surface) 111a for supporting a substrate (wafer) W and an annular region (a ring support surface) 111b for supporting the ring assembly 112. The annular region 111b of the main body 111 surrounds the central region 111a of the main body 111 in a plan view. The substrate W is placed on the central region 111a of the main body 111, and the ring assembly 112 is disposed on the annular region 111b of the main body 111 to surround the substrate W on the central region 111a of the main body 111. In an embodiment, the main body 111 includes a base and an electrostatic chuck. The base includes a conductive member. The conductive member of the base functions as a lower electrode. The electrostatic chuck is placed on the base. The top surface of the electrostatic chuck has the substrate support surface 111a. The ring assembly 112 includes one or more annular members. At least one of the one or more annular members is an edge ring. Although not illustrated, the substrate support 11 may include a temperature regulation module configured to regulate a temperature of at least one of the electrostatic chuck, the ring assembly 112, and the substrate to a target temperature. The temperature regulation module may include a heater, a heat transfer medium, a flow path, or a combination thereof. A heat transfer fluid, such as brine or gas, flows through the flow path. The substrate support 11 may include a heat transfer gas supplier configured to supply a heat transfer gas to a space between a rear surface of the substrate W and the substrate support surface 111a.

The shower head 13 is configured to introduce at least one processing gas from the gas supplier 20 into the plasma processing space 10s. The shower head 13 includes at least one gas supply port 13a, at least one gas diffusion chamber 13b, and a plurality of gas inlet ports 13c. The processing gas supplied to the gas supply port 13a passes through the gas diffusion chamber 13b and is introduced into the plasma processing space 10s from the plurality of gas inlet ports 13c. In addition, the shower head 13 includes a conductive member. The conductive member of the shower head 13 functions as an upper electrode. In addition to the shower head 13, the gas introduction part may include one or more side gas injectors SGI installed in one or more openings formed in the sidewall 10a.

The gas supplier 20 may include at least one gas source 21 and at least one flow rate controller 22. In an embodiment, the gas supplier 20 is configured to supply at least one processing gas from a corresponding gas source 21 to the shower head 13 via a corresponding flow rate controller 22. Each flow rate controller 22 may include, for example, a mass flow controller or a pressure-controlled flow rate controller. The gas supplier 20 may include at least one flow rate modulation device configured to modulate or pulse the flow rate of the at least one processing gas.

The power supply 30 includes an RF power supply 31 coupled to the plasma processing chamber 10 via at least one impedance matching circuit. The RF power supply 31 is configured to supply at least one RF signal (RF power) such as a source RF signal and a bias RF signal to the conductive member of the substrate support 11 and/or the conductive member of the shower head 13. As a result, plasma is formed from the at least one processing gas supplied to the plasma processing space 10s. Therefore, the RF power supply 31 may function as at least a portion of the plasma generator 12. By supplying the bias RF signal to the conductive member of the substrate support 11, a bias potential is generated in the substrate W, and an ionic component in the formed plasma can be drawn into the substrate W.

In an embodiment, the RF power supply 31 includes a first RF generator 31a and a second RF generator 31b. The first RF generator 31a is coupled to the conductive member of the substrate support 11 and/or the conductive member of the shower head 13 via at least one impedance matching circuit, and is configured to generate a source RF signal (source RF power) for plasma generation. In an embodiment, the source RF signal has a frequency in the range of 13 MHz to 150 MHz. In an embodiment, the first RF generator 31a may be configured to generate multiple source RF signals having different frequencies. The generated one or more source RF signals are supplied to the conductive member of the substrate support 11 and/or the conductive member of the shower head 13. The second RF generator 31b is coupled to the conductive member of the substrate support 11 via at least one impedance matching circuit, and is configured to generate a bias RF signal (bias RF power). In an embodiment, the bias RF signal has a lower frequency than the source RF signal. In an embodiment, the bias RF signal has a frequency in the range of 400 kHz to 13.56 MHz. In an embodiment, the second RF generator 31b may be configured to generate multiple bias RF signals having different frequencies. The generated one or more bias RF signals are supplied to the conductive member of the substrate support 11. In addition, in various embodiments, at least one of the source RF signal and the bias RF signal may be pulsed.

The power supply 30 may include a DC power supply 32 coupled to the plasma processing chamber 10. The DC power supply 32 includes a first DC generator 32a and a second DC generator 32b. In an embodiment, the first DC generator 32a is connected to the conductive member of the substrate support 11 and is configured to generate a first DC signal. The generated first DC signal is applied to the conductive member of the substrate support 11. In an embodiment, the first DC signal may be applied to another electrode such as an electrode in an electrostatic chuck. In an embodiment, the second DC generator 32b is connected to the conductive member of the shower head 13 and is configured to generate a second DC signal. The generated second DC signal is applied to the conductive member of the shower head 13. In various embodiments, the first and second DC signals may be pulsed. The first and second DC generators 32a and 32b may be provided in addition to the RF power supply 31, or the first DC generator 32a may be provided in place of the second RF generator 31b.

The exhaust system 40 may be connected to, for example, a gas discharge port 10e provided in the bottom portion of the plasma processing chamber 10. The exhaust system 40 may include a pressure regulation valve and a vacuum pump. By the pressure regulation valve, an internal pressure of the plasma processing space 10s is regulated. The vacuum pump may include a turbo molecular pump, a dry pump, or a combination thereof.

An exhaust ring 50 (an exhaust ring assembly) is arranged around the substrate support 11. The exhaust ring 50 is an annular member and is provided between the sidewall of the plasma processing chamber 10 and the sidewall of the substrate support 11. The exhaust ring 50 separates the interior of the plasma processing chamber 10 into the plasma processing space 10s and an exhaust space 10t. The exhaust ring 50 has a double structure in which two plate-shaped members are overlapped with each other.

### [Exhaust Ring]

In the exhaust ring having the double structure, there is a trade-off relationship in that, when an opening ratio due to the exhaust holes is high, the exhaust efficiency is improved, but plasma is likely to leak from the plasma processing space 10s to the exhaust space 10t, and when the opening ratio is low, plasma is less likely to leak, but the exhaust efficiency is reduced. That is, in order to efficiently exhaust the exhaust gas from the plasma processing space 10s, there is a method of enlarging the exhaust hole of the exhaust ring 50 to increase the conductance, but this leads to the leakage of plasma from the exhaust ring 50. On the other hand, in the exhaust ring 50 in which the exhaust hole is made small so that plasma does not leak and the effect of confining plasma is strengthened, the flow of the exhaust gas is obstructed, which causes a decrease in the exhaust efficiency. In consideration of such a trade-off, the present embodiment proposes a shape of the exhaust ring 50 that achieves both improvement of exhaust efficiency and suppression of plasma leakage.

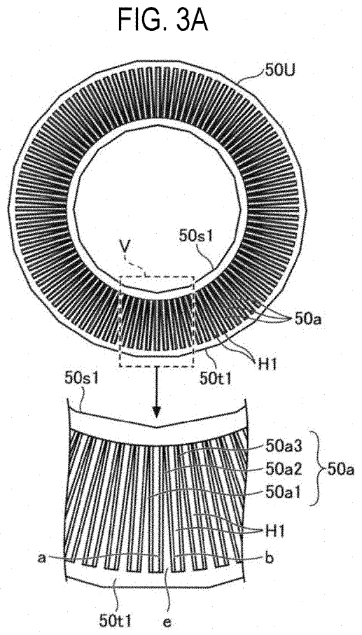

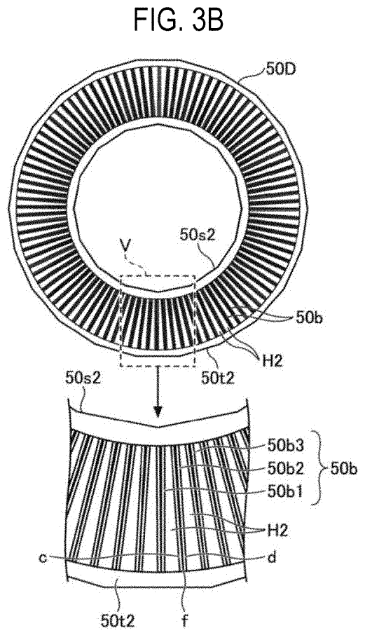

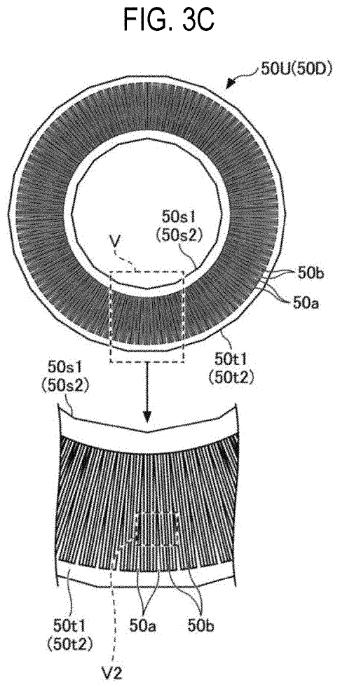

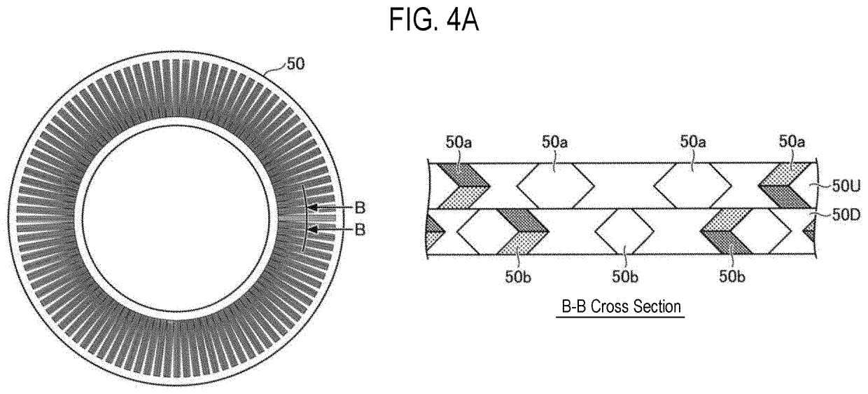

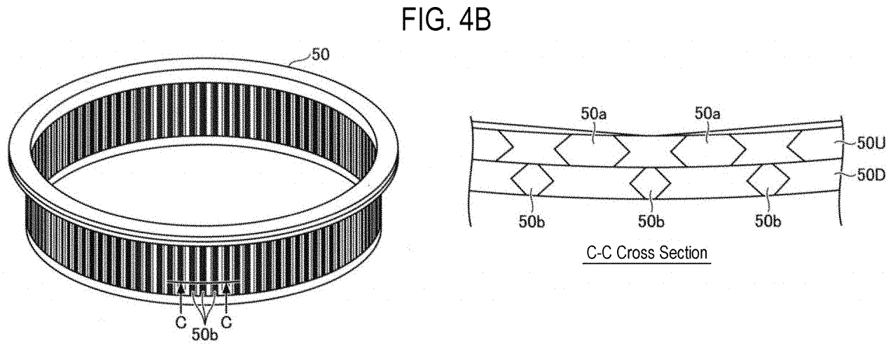

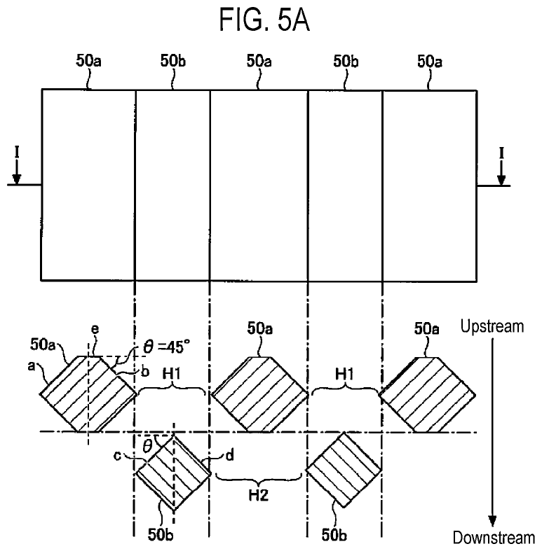

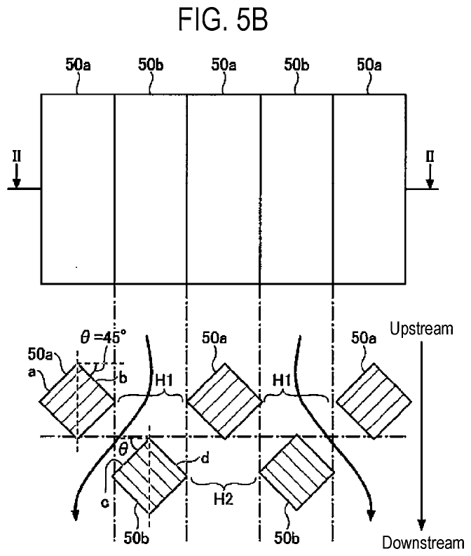

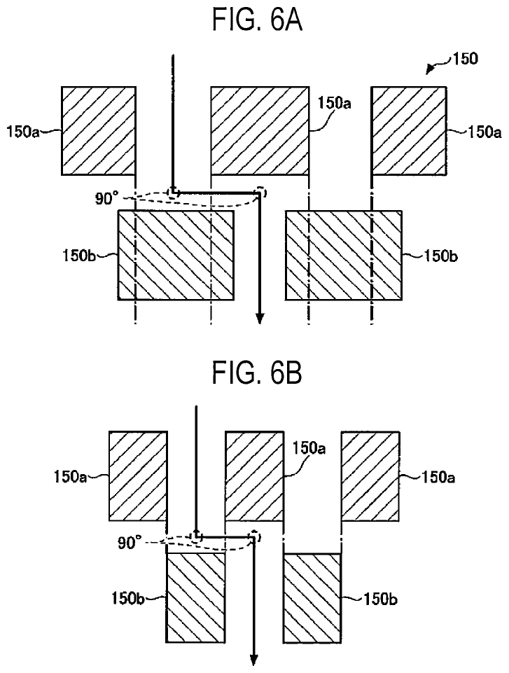

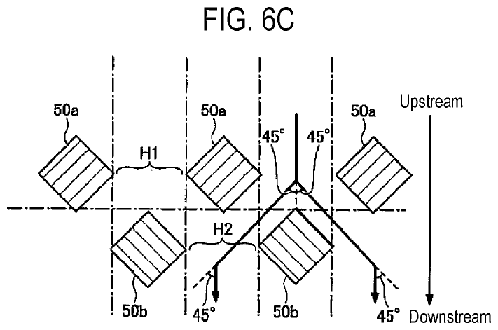

The shape of the exhaust ring 50 according to the present embodiment will be described with reference to FIGS. 3A to 6C. FIGS. 3A to 3C are views illustrating examples of respective members of the exhaust ring 50 having a double structure according to an embodiment. FIGS. 4A and 4B are views illustrating examples of a parallel type exhaust ring 50 and a cylindrical type exhaust ring 50 according to an embodiment. FIGS. 5A and 5B are a top view and a cross-sectional view of a portion of the exhaust ring 50 according to an embodiment. FIGS. 6A to 6C are views illustrating examples of flows of gas passing through exhaust rings 50 according to an embodiment and a comparative example.

As illustrated in FIGS. 3A to 3C, the exhaust ring 50 includes a first member 50U (first annular member) of an annular shape having a plurality of exhaust holes and a second member 50D (second annular member) of an annular shape having a plurality of exhaust holes. The first member 50U and the second member 50D are arranged to overlap each other. FIG. 3A is a top view of the first member 50U, and FIG. 3B is a top view of the second member 50D. FIG. 3C is a view obtained when the exhaust ring 50 having a double structure in which the first member 50U and the second member 50D are overlapped with each other is viewed from above. The exhaust ring 50 is arranged horizontally around the substrate support 11 as illustrated in FIG. 2 in the state in which the radial directions of the first member 50U and the second member 50D are horizontally overlapped with each other to form a double structure. That is, the exhaust rings 50 illustrated in FIG. 2 and FIGS. 3A to 3C are parallel type exhaust rings.

The first member 50U of FIG. 3A includes circular inner and outer frames 50s1 and 50t1, which are concentrically arranged, and a plurality of rod-shaped base materials 50a (first rod-shaped portions), which are radically bridged between the circular inner and outer frames 50s1 and 50t1 over 360 degrees. The plurality of base materials 50a are arranged at equal pitches between the inner and outer frames 50s1 and 50t1, whereby a plurality of slits are formed radially between the inner and outer frames 50s1 and 50t1. The plurality of radially-formed slits function as exhaust holes H1 (first exhaust holes) for exhausting gas.

Referring to an enlarged view (lower figure) of a region V of the first member 50U in FIG. 3A, the top surfaces of the base materials 50a including the base materials 50a1, 50a2, 50a3 . . . are chamfered. For example, opposite sides of the top surface of each base material 50a2 are chamfered, and inclined surfaces a and b are formed on the opposite sides of the top surface. That is, the top surface of each base material 50a has a tapered shape. In the example of FIG. 3A, a surface e of the center of the top surface of each base material 50a is flat, but the flat surface e may be omitted. When there is the flat surface e, as illustrated in the right figure of FIG. 4A and FIG. 5A, each base material 50a has a shape in which a flat surface is present in the center of the top surface and inclined surfaces are present on opposite sides of the same. When there is no flat surface e, as illustrated in FIG. 5B, each base material 50a has a shape in which there is no flat surface in the center of the top surface and an apex is formed in the center by inclined surfaces.

The second member 50D of FIG. 3B includes circular inner and outer frames 50s2 and 50t2, which are concentrically arranged, and a plurality of rod-shaped base materials 50b (second rod-shaped portions), which are radically bridged between the circular inner and outer frames 50s2 and 50t2 over 360 degrees. The plurality of base materials 50b are arranged at equal pitches between the inner and outer frames 50s2 and 50t2, whereby a plurality of slits are formed radially between the inner and other frames 50s2 and 50t2. The plurality of radially-formed slits function as exhaust holes H2 (second exhaust holes) for exhausting gas.

Referring to an enlarged view (lower figure) of a region V of FIG. 3B having the same arrangement as the region V of FIG. 3A, the top surfaces of the base materials 50b including the base materials 50b1, 50b2, 50b3 . . . are chamfered. For example, opposite sides of the top surface of each base material 50b2 are chamfered, and inclined surfaces c and d are formed on the opposite sides of the top surface. That is, the top surface of each base material 50b has a tapered shape. In the example of FIG. 3B, a surface f of the center of the top surface of each base material 50a is flat, but the flat surface f may be omitted. When there is the flat surface f, as illustrated in the right figure of FIG. 4A, each base material 50b has a shape in which a flat surface is present in the center of the top surface and inclined surfaces are present on opposite sides of the same. When there is no flat surface f, as illustrated in FIGS. 5A and 5B, each base material 50b has a shape in which there is no flat surface in the center of the top surface and an apex is formed in the center by inclined surfaces.

Top surfaces of portions other than the exhaust holes of the first member 50U and top surfaces of portions other than the exhaust holes of the second member 50D become end surfaces on the upstream side through which gas flows. This makes it possible to improve the flow of the exhaust gas. The portions of the first member 50U other than the exhaust holes H1 are the portions of the base materials 50a, and the portions of the second member 50D other than the exhaust holes H2 are the portions of the base materials 50b.

The inner frame 50s1 and the inner frame 50s2 have the same diameter, and the outer frame 50t1 and the outer frame 50t2 have the same diameter. Therefore, in the state of FIG. 3C in which the first member 50U is stacked on the second member 50D, the inner frame 50s2 and the outer frame 50t2 are arranged under the inner frame 50s1 and the outer frame 50t1 and is invisible in a top view.

In the exhaust ring 50 according to the present embodiment, the first member 50U is stacked on the second member 50D. As illustrated in the B-B cross section of FIG. 4A, no clearance (gap) is provided between the first member 50U and the second member 50D. Even if no gap is provided between the first member 50U and the second member 50D, the base materials 50a and the base materials 50b do not come into contact with each other so that exhaust passages are formed. However, a gap may be provided between the first member 50U and the second member 50D. The exhaust ring 50 has a shape in which the first member 50U and the second member 50D are integrated with each other, and may have a configuration in which slits are formed between the base materials 50a and the base materials 50b as illustrated in FIGS. 4A and 4B.

As illustrated in FIGS. 5A and 5B, the horizontal width of the plurality of base materials 50a of the first member 50U is the same as the width of the slits (exhaust holes H2) between the plurality of base materials 50b of the second member 50D. The horizontal width of the plurality of base materials 50b of the second member 50D is the same as the width of the slits (exhaust holes H1) between the plurality of base materials 50a of the first member 50U. In this way, the phases of the slits of the first member 50U and the slits of the second member 50D are shifted. As a result, in the state in which the first member 50U is stacked on the second member 50D, as partially illustrated in FIGS. 5A and 5B, the base materials 50b having, in a top view, the same width and length as the width and length of the slits (exhaust holes H1) formed in the first member 50U are arranged below the slits. In addition, the base materials 50a having, in a top view, the same width and length as the width and length of the slits (exhaust holes H2) are arranged on the slits formed in the second member 50D.

As a result, as illustrated in the enlarged view of the region V of FIG. 3C having the same arrangement as the region V of FIGS. 3A and 3B and FIGS. 5A and 5B, the exhaust space 10t is invisible from the plasma processing space 10s side in a top view.

In addition, the exhaust holes H in the first member 50U and the exhaust holes H in the second member 50D do not overlap each other when viewed from the top surface side, that is, in the direction in which the gas flows. In addition, the portions of the first member 50U other than the exhaust holes H1 and the portions of the second member 50D other than the exhaust holes H2 do not overlap each other when viewed in the flow direction of the exhaust gas. This will be described with reference to FIGS. 5A and 5B.

The upper figure of FIG. 5A is a view schematically illustrating the region V2 of the enlarged view (the lower figure) of FIG. 3C in the state of being further enlarged. The lower figure of FIG. 5A is a view illustrating a cross section taken along line I-I in the upper figure of FIG. 5A. As indicated by the arrows in the lower figure of FIG. 5A, the exhaust gas flows from the top to the bottom of the drawing sheet surface. That is, the gas flows from above the base materials 50a of the first member 50U to the downstream side by passing through the exhaust holes H1 between the base materials 50a and passing through the exhaust holes H2 between the base materials 50b of the second member 50D. When the exhaust ring 50 is arranged in the plasma processing apparatus 1, the upstream side is the plasma processing space 10s, and the downstream side is the exhaust space 10t.

As illustrated in the lower figure of FIG. 5A, the exhaust holes H1 between the base materials 50a of the first member 50U and the exhaust holes H2 between the base materials 50b of the second member 50D do not overlap each other when viewed in the exhaust gas flow direction. However, due to machining, some overlap is allowed. In addition, the portions of the first member 50U other than the exhaust holes H1 and the portions of the second member 50D other than the exhaust holes H2 do not overlap each other when viewed in the exhaust gas flow direction. However, due to machining, some overlap is allowed.

Furthermore, at least the upstream-side end surfaces a, b, c, and d of the portions of the first member 50U other than the exhaust holes H1 and the portion of the second member 50D other than the exhaust holes H2 have a tapered shape. The tapered end surfaces a, b, c, and d are formed at an angle of 45 degrees with respect to the exhaust gas flow direction in the vertical direction. However, without being limited thereto, at least the upstream-side tapered end surfaces a, b, c, and d may be formed at an angle of 45 degrees or more with respect to the exhaust gas flow direction in the vertical direction.

The sizes of the base materials 50a and the base materials 50b may be varied. The following changes may also be made to the shapes of the base materials 50a and the base materials 50b. For example, in the example of FIG. 5B, the cross-sectional shapes of the base materials 50a and the base materials 50b are rhombuses having the same shape. In contrast, in the example of FIG. 5A, the cross-sectional shapes of the base materials 50a and the base materials 50b are different from each other. The cross-sectional shape of the base materials 50b is a rhombus, but the cross-sectional shape of the base materials 50a is a hexagon. That is, as illustrated in FIG. 5A, the vertices of the base materials 50a on the upstream side in the direction in which the exhaust gas flows and the opposing surfaces may be formed flat.

In addition, the left and right vertices of the base materials 50a and the base materials 50b may be formed flat. In order to improve the gas flow, it may be better not to flatten the vertices (angles formed by the end surfaces c and d) of the base materials 50b on the downstream side in the gas flow direction. When the vertices of the base materials 50b on the downstream side in the gas flow direction are formed at an angle of 90 degrees or less by the end surfaces c and d, the shapes of the base materials 50b may be a rhombus, a hexagon, or a triangle. Other shapes may be used. When the vertices of the base materials 50a on the upstream side in the gas flow direction are formed at an angle of 90 degrees or less by the end surfaces a and b, the shape of the base materials 50a may be a rhombus, a hexagon, or a triangle.

In the exhaust rings 150 according to a comparative example illustrated in FIGS. 6A and 6B, the cross sections of the members 150a and the members 150b are rectangular, and the end surfaces of these members do not have a tapered shape. In this case, in both of FIG. 6A in which the members 150a and the members 150b overlap when viewed in the direction in which the gas flows on the drawing sheet surface and FIG. 6B in which the members 150a and the members 150b do not overlap when viewed in the direction in which the gas flows on the drawing sheet surface, the folding angle of the exhaust gas when flowing from the base materials 50a to the base materials 50b becomes about 90 degrees. In addition, the folding angle of the exhaust gas when flowing from the base materials 50b to the downstream side of the base materials 50b becomes about 90 degrees, and thus the total folding angle of the exhaust gas passing through the exhaust ring 50 becomes approximately 180 degrees.

In contrast, according to the exhaust ring 50 including the base materials 50a and 50b having the shapes and arrangements according to the present embodiment, as illustrated in FIGS. 5A and 5B, when the cross sections of the base materials 50a and 50b are viewed, the angle is formed at 45 degrees with respect to the vertical direction of the gas flow. As a result, as illustrated in FIG. 6C, the folding angle of the exhaust gas when flowing from the base materials 50a to the base materials 50b becomes about 45 degrees, and the folding angle of the exhaust gas when flowing from the base materials 50b to the downstream side of the base materials 50b becomes about 45 degrees. Therefore, the total folding angle of the exhaust gas passing through the exhaust ring 50 is approximately 90 degrees. As a result, with the exhaust ring 50 according to the present embodiment, the conductance of the exhaust gas becomes higher than that in the comparative example, and the exhaust efficiency can be improved.

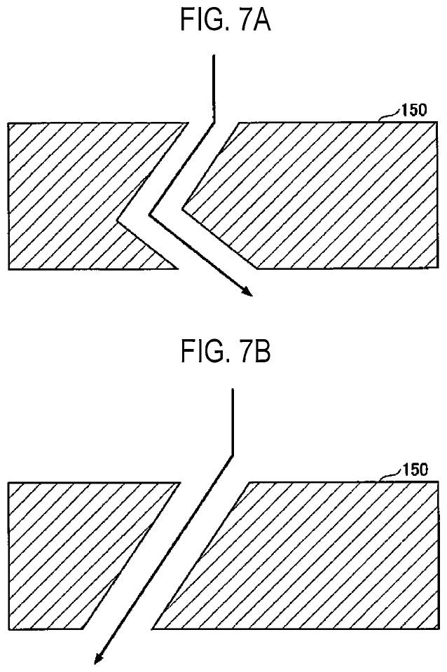

FIGS. 7A and 7B are views illustrating examples of flows of gas passing through exhaust rings in another comparative example. FIG. 7A illustrates an example of an exhaust ring 150 provided with a chevron (mountain-shaped) slit as an exhaust hole. FIG. 7B is an example of an exhaust ring 150 provided with an oblique slit as an exhaust hole. In these cases, opposite surfaces can be shielded with one slit. Compared to these exhaust rings 150, in the exhaust ring 50 according to the present embodiment, as illustrated in the base materials 50a and the base materials 50b of FIG. 6C, since the volume fraction of the exhaust holes H1 and the exhaust holes H2 in the cross section of the exhaust ring 50 is high, the exhaust efficiency is higher than that in the comparative example. In addition, in the slit shapes of FIGS. 7A and 7B, it is difficult to cover the entire surfaces of the exhaust hole with thermally-sprayed films through thermal spraying to be described later.

As described above, with the exhaust ring 50 according to the present embodiment, since the volume fraction of the exhaust holes H in the cross section of the exhaust ring 50 is high, the exhaust efficiency can be improved. In addition, the exhaust ring 50 of the present embodiment has a structure in which the exhaust space 10t is not visible from the side of the plasma processing space 10s. This makes it possible to suppress leakage of plasma. Therefore, with the exhaust ring 50 of the present embodiment, it is possible to achieve both improvement of exhaust efficiency and suppression of plasma leakage.

In the above, the parallel type exhaust ring 50 in which the first member 50U and the second member 50D are arranged to be overlapped with each other without a gap has been described. However, the first member 50U and the second member 50D may be arranged to be overlapped with each other while being spaced apart from each other.

As illustrated in FIG. 4B, a cylindrical exhaust ring 50 may be used. In this case, the first member 50U and the second member 50D are arranged to be overlapped with each other in the vertical direction. In this case, the first member 50U is arranged inside and the second member 50D is arranged outside. Exhaust gas is exhausted from the inside to the outside of the cylindrical exhaust ring 50. That is, the exhaust gas flow direction is oriented radially outward from the inside of the exhaust ring 50.

Referring to the C-C cross section of FIG. 4B, the first member 50U and the second member 50D are also arranged to be overlapped with each other in the cylindrical exhaust ring 50 without any spacing therebetween. However, the first member 50U and the second member 50D may be arranged to be overlapped with each other with a gap therebetween.

In any type of exhaust ring 50, the first member 50U and the second member 50D may be arranged to be overlapped with each other at a distance of at least half the thickness of the second member 50D in the exhaust gas flow direction. That is, the vertices of the base materials 50b of the second member 50D oriented toward the upstream side with respect to the exhaust gas flow direction may overlap the first member 50U in the exhaust gas flow direction when the overlapping is not in excess of half the thickness of the base materials 50b. When the second member 50D overlaps the first member 50U in excess of half the thickness of the base materials 50b in the exhaust gas flow direction, the exhaust efficiency may be deteriorated.

In addition, the first member 50U and the second member 50D may be formed integrally with each other. In the parallel type exhaust ring 50 illustrated in FIG. 4A, the first member 50U and the second member 50D may also be formed integrally with each other.

In the above, the exhaust ring 50, which can achieve both improvement of exhaust efficiency and suppression of plasma leakage by preventing deterioration of exhaust efficiency when the exhaust ring 50 has a double structure by optimizing the shape, has been described.

### [Thermal Spraying]

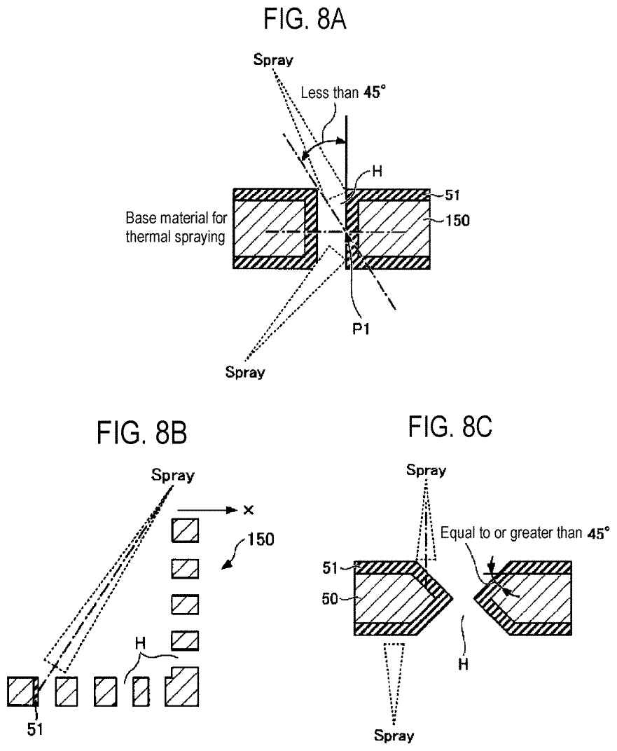

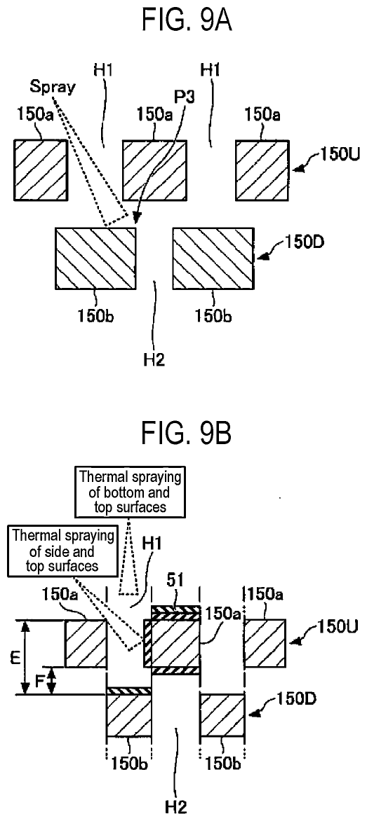

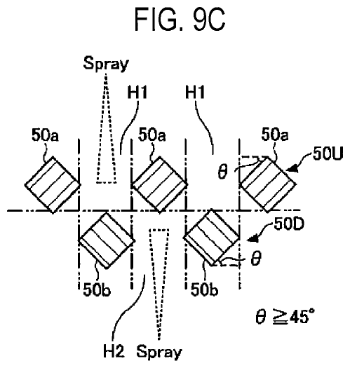

Next, with reference to FIGS. 8A to 8C and FIGS. 9A to 9C, an example of a method of thermal spraying an exhaust ring 50 according to an embodiment will be described in comparison with an exhaust ring 150 of a comparative example. FIGS. 8A to 8C and FIGS. 9A to 9C are views illustrating examples of a method of thermal spraying the exhaust ring 50 according to an embodiment in comparison with the exhaust ring 150 of the comparative example. The exhaust ring 50 has a plurality of exhaust holes H configured to allow communication between the plasma processing space 10s and the exhaust space 10t in order to exhaust the exhaust gas from the plasma processing space 10s to the exhaust space 10t. The surface of the exhaust ring 50 is exposed to plasma, including the inner portions of the exhaust holes H. Therefore, a thermally-sprayed film is formed on the surfaces of the first member 50U and the second member 50D. The surfaces of the first member 50U and the second member 50D are preferably coated with a plasma-resistant thermally-sprayed film such as Y₂O₃ or the like.

However, as illustrated in FIG. 8A, in a rectangular exhaust ring 150 of the comparative example, a position P1 in which particles of the sprayed thermally-spraying material do not reach the inner portion of an exhaust hole is generated depending on an aspect ratio of the exhaust hole. In the example of FIG. 8A, the angle of the thermally-spraying material to be sprayed with respect to the sidewall of the exhaust hole H is less than 45 degrees, and the thermally-spraying material does not reach the position P1 due to the narrow exhaust hole. Thus, the entire surface of the exhaust hole H cannot be coated with the thermally-sprayed film.

In the example of FIG. 9A, during thermal spraying, the spray may not reach the portion in which the first member 150U and the second member 150D overlap (for example, P3). As a countermeasure, for example, changing the spraying angle of the thermally-spraying material may be considered, but there is a concern that the thickness of the thermally-sprayed film will be uneven. As illustrated in FIG. 8B, depending on the shape of the exhaust ring 50, the thermally-spraying material cannot be sprayed at an angle. Thus, the inner portions of the exhaust holes H may not be coated with the thermally-sprayed film. In the example of FIG. 8B, when the thermally-spraying material is sprayed while moving in the x direction, the inner portion of the corner of the exhaust ring 50 cannot be subjected to thermal spraying.

In the example of FIG. 9B, the thermally-spraying material is sprayed to the first member 150U and the second member 150D which have a large aspect ratio E of exhaust holes and are arranged at intervals to secure a gas flow path F. In this case, in a first round of thermal spraying, the side surface of the exhaust hole H and the top surface of the first member 150U are subjected to thermal spraying. Subsequently, in a second round of thermal spraying, the bottom surface of the exhaust hole H (the top surface of the second member 150D) and the top surface of the first member 150U are subjected to thermal spraying. Then, on the top surface of the first member 150U which has been subjected to thermal spraying twice, since the number of times of thermal spraying is larger than that of other portions, a difference is caused in the thickness of a thermally-sprayed film 51. As a result, the thermally-sprayed film 51 cannot be formed uniformly.

In contrast, in the exhaust ring 50 according to the present embodiment, the tapered end surfaces forming the exhaust hole H are formed at an angle θ of 45 degrees or more with respect to the vertical direction of the exhaust gas flow. Thus, the entire inner portion of the exhaust hole H can be coated with the thermally-sprayed film. Therefore, as illustrated in FIG. 9C, even when the thermally-spraying material is sprayed perpendicularly to the exhaust ring 50, it is possible to obtain a thermal spraying angle θ of 45 degrees or more with respect to the interior of the exhaust hole H1 or H2. Therefore, a thermally-sprayed film can be formed on the entire exhaust hole H. That is, with the exhaust ring 50 according to the present embodiment, the thermally-spraying material may be sprayed vertically while moving the thermally-spraying material horizontally with respect to the exhaust ring 50. In the exhaust ring 50 according to the present embodiment, the interior of the exhaust hole H can be coated with a single round of thermal spraying. As a result, the film thickness can be made uniform.

As described above, with the exhaust ring 50 according to the present embodiment, the entire shape and the shape of the inlets in the direction in which the exhaust gas flows are optimized. As a result, while maintaining a high volume fraction of the exhaust holes H in the cross sections of the base materials 50a and the base materials 50b, there is no gap in the exhaust ring 50 when viewed from the side of the plasma processing space 10s, and thus plasma leakage can be suppressed. Furthermore, since the exhaust gas can be exhausted when the folding angle of the exhaust gas flow in the exhaust ring 50 is less than 90 degrees, the exhaust efficiency can be improved. In this way, it is possible to provide the exhaust ring 50 that achieves both improvement in exhaust efficiency and suppression of plasma leakage. In addition, according to the shape of the exhaust ring 50, the surface of the exhaust ring 50 can be uniformly coated with the thermally-sprayed film.

The plasma processing apparatus 1 of the present disclosure is applicable to any type of apparatus of an atomic layer deposition (ALD) apparatus, a capacitively coupled plasma (CCP) apparatus, an inductively coupled plasma (ICP) apparatus, a radial line slot antenna (RLSA) apparatus, an electron cyclotron resonance plasma (ECRP) apparatus, or a helicon wave plasma (HWP) apparatus.

According to an aspect, it is possible to provide an exhaust ring capable of achieving both improvement of exhaust efficiency and suppression of plasma leakage.

It should be understood that the exhaust rings and the plasma processing apparatus according to the embodiments disclosed herein are exemplary in all respects and are not restrictive. The embodiments can be modified and improved in various forms without departing from the scope and spirit of the appended claims. The matters described in the aforementioned embodiments may have other configurations to the extent that they are not inconsistent, and may be combined to the extent that they are not inconsistent.

What is claimed is:

1. An exhaust ring assembly disposed around a substrate support, comprising:
a first annular member having a plurality of first exhaust holes and a plurality of first rod-shaped portions alternately arranged in a circumferential direction, each of the plurality of first exhaust holes extending in a radial direction and each of the plurality of first rod-shaped portions extending in the radial direction; and
a second annular member disposed below the first annular member and having a plurality of second exhaust holes and a plurality of second rod-shaped portions alternately arranged in the circumferential direction, each of the plurality of second exhaust holes extending in the radial direction and each of the plurality of second rod-shaped portions extending in the radial direction,
wherein the plurality of first rod-shaped portions and the plurality of second rod-shaped portions do not overlap each other when viewed from above, and
wherein at least one of each of the plurality of first rod-shaped portions and each of the plurality of second rod-shaped portions has an upwardly-tapered shape.

2. The exhaust ring assembly of claim 1, wherein each of the plurality of first rod-shaped portions has the upwardly-tapered shape, and each of the plurality of second rod-shaped portions has the upwardly-tapered shape.

3. The exhaust ring assembly of claim 1, wherein the at least one of each of the plurality of first rod-shaped portions and each of the plurality of second rod-shaped portions has a downwardly-tapered shape.

4. The exhaust ring assembly of claim 3, wherein each of the plurality of first rod-shaped portions has the downwardly-tapered shape, and each of the plurality of second rod-shaped portions has the downwardly-tapered shape.

5. The exhaust ring assembly of claim 4, wherein the at least one of each of the plurality of first rod-shaped portions and each of the plurality of second rod-shaped portions has an inclined surface inclined at an angle of 45 degrees or more in a horizontal direction with respect to the upwardly-tapered shape.

6. The exhaust ring assembly of claim 4, wherein the first annular member further includes a first thermally-sprayed film formed on the plurality of first rod-shaped portions, and the second annular member further includes a second thermally-sprayed film formed on the plurality of second rod-shaped portions.

7. The exhaust ring assembly of claim 4, wherein a gap is formed between the plurality of first rod-shaped portions and the plurality of second rod-shaped portions, and the gap is equal to or greater than a half of a thickness of the second annular member.

8. The exhaust ring assembly of claim 4, wherein a height of a lower end portion of each of the plurality of first rod-shaped portions and a height of an upper end portion of each of the plurality of second rod-shaped portions are substantially identical to each other.

9. The exhaust ring assembly of claim 4, wherein the plurality of first rod-shaped portions and the plurality of second rod-shaped portions overlap each other when viewed from a side.

10. The exhaust ring assembly of claim 4, wherein the first annular member and the second annular member are formed integrally with each other.

11. The exhaust ring assembly of claim 1, wherein the at least one of each of the plurality of first rod-shaped portions and each of the plurality of second rod-shaped portions has an inclined surface inclined at an angle of 45 degrees or more in a horizontal direction with respect to the upwardly-tapered shape.

12. The exhaust ring assembly of claim 1, wherein the first annular member further includes a first thermally-sprayed film formed on the plurality of first rod-shaped portions, and the second annular member further includes a second thermally-sprayed film formed on the plurality of second rod-shaped portions.

13. The exhaust ring assembly of claim 1, wherein the first annular member is formed integrally with the second annular member.

14. An exhaust ring assembly disposed around a substrate support, comprising:
a first annular member including a plurality of first exhaust holes and a plurality of first rod-shaped portions alternately arranged in a circumferential direction, each of the plurality of first exhaust holes extending in a vertical direction and each of the plurality of first rod-shaped portion extending in the vertical direction; and
a second annular member disposed around the first annular member and including a plurality of second exhaust holes and a plurality of second rod-shaped portions alternately arranged in the circumferential direction, each of the plurality of second exhaust holes extending in the vertical direction and each of the plurality of second rod-shaped portions extending in the vertical direction,
wherein the plurality of first rod-shaped portions and the plurality of second rod-shaped portions do not overlap each other in a radial direction, and
wherein at least one of each of the plurality of first rod-shaped portions and each of the plurality of second rod-shaped portions has an inwardly-tapered shape or an outwardly-tapered shape.

15. The exhaust ring assembly of claim 14, wherein each of the plurality of first rod-shaped portions has at least one of the inwardly-tapered shape and the outwardly-tapered shape, and each of the plurality of second rod-shaped portions has at least one of the inwardly-tapered shape and the outwardly-tapered shape.

16. A plasma processing system, comprising:
a plasma processing chamber having at least one gas inlet and at least one gas outlet;
a substrate support disposed inside the plasma processing chamber; and
an exhaust ring assembly disposed around the substrate support,
wherein the exhaust ring assembly includes:
a first annular member having a plurality of first exhaust holes and a plurality of first rod-shaped portions alternately arranged in a circumferential direction, each of the plurality of first exhaust holes extending in a radial direction and each of the plurality of first rod-shaped portions extending in the radial direction; and
a second annular member disposed below the first annular member and having a plurality of second exhaust holes and a plurality of second rod-shaped portions alternately arranged in the circumferential direction, each of the plurality of second exhaust holes extending in the radial direction and each of the plurality of second rod-shaped portions extending in the radial direction,
wherein the plurality of first rod-shaped portions and the plurality of second rod-shaped portions do not overlap each other when viewed from above, and
wherein at least one of each of the plurality of first rod-shaped portions and each of the plurality of second rod-shaped portions has an upwardly-tapered shape.
